(19) United States
(12) Patent Application Publication
(10) Pub. No.: US 2018/0315357 A1
(43) Pub. Date: Nov. 1, 2018

(54) Electronic Devices Having Displays With Optical Windows

(71) Applicant: Apple Inc., Cupertino, CA (US)

(72) Inventors: Donghee Nam, San Jose, CA (US); Bhadrinarayana Lalgudi Visweswaran, Santa Clara, CA (US); Cheng Chen, San Jose, CA (US); Meng-Huan Ho, San Jose, CA (US); Nathan K. Gupta, San Francisco, CA (US); Rui Liu, San Jose, CA (US); Sebastian Knitter, San Francisco, CA (US); Sudirukkuge T. Jinasundera, San Jose, CA (US); Tsung-Ting Tsai, Cupertino, CA (US); Weibo Cheng, Santa Clara, CA (US)

(21) Appl. No.: 15/882,908

(22) Filed: Jan. 29, 2018

Related U.S. Application Data
(60) Provisional application No. 62/492,708, filed on May 1, 2017.

(51) Int. Cl. G09F 13/22; H01L 51/52; H01L 27/32

(52) U.S. Cl. CPC G09F 13/22; G09F 2013/222; H01L 27/3227; H01L 51/5293

(57) ABSTRACT

An electronic device may be provided with a display. The display may have a display cover layer. The display may have an active area with pixels and an inactive area with dummy pixels. The dummy pixels may have structures that are optically matched to the pixels so that the dummy pixels and pixels have similar visual appearances when the display is off. An optical window may be formed in the inactive area. A light-based component such as an ambient light sensor, proximity sensor, or image sensor may be mounted in the electronic device in alignment with the optical window. A polarizer layer may overlap the active and inactive areas of the display. An opening in the polarizer or a bleached unpolarized portion of the polarizer may be aligned with the optical window.

This application claims the benefit of provisional patent application No. 62/492,708, filed May 1, 2017, which is hereby incorporated by reference herein in its entirety.

### BACKGROUND

This relates generally to electronic devices, and, more particularly, to electronic devices with displays.

Electronic devices such as laptop computers, cellular telephones, and other equipment are sometimes provided with displays. In some devices, displays occupy relatively large portions of the devices.

It can be challenging to incorporate desired functionality into devices such as these. For example, it may be difficult to incorporate light-based devices such as light sensors and cameras into a device with a display without disturbing the appearance of the display.

### SUMMARY

An electronic device may be provided with a display. The display may have a display cover layer. The display cover layer may overlap a touch sensor and an inorganic light-emitting diode display layer.

The display may have an active area with pixels and an inactive area with dummy pixels. The dummy pixels may have structures that are optically matched to the pixels so that the dummy pixels and pixels have similar visual appearances when the display is off. In an organic light-emitting diode display, dummy pixels may be formed by disconnecting organic light-emitting diodes from thin-film transistor circuitry, by omitting cathode structures, emissive organic material, or other pixel components, or otherwise disabling the dummy pixels to prevent the dummy pixels from being capable of emitting light.

An optical window may be formed in the inactive area. A light-based component such as an ambient light sensor, proximity sensor, or image sensor may be mounted in the electronic device in alignment with the optical window. A polarizer layer may overlap the active and inactive areas of the display. An opening in the polarizer or a unpolarized portion of the polarizer may be aligned with the optical window.

### BRIEF DESCRIPTION OF THE DRAWINGS

FIG. 1 is a schematic diagram of an illustrative electronic device in accordance with an embodiment.

FIG. 2 is a perspective view of an electronic device having optical windows for light-based components such as light sensors in accordance with an embodiment.

FIG. 3 is a top view of a portion of an illustrative electronic device having windows for light-based components in accordance with an embodiment.

FIG. 4 is a cross-sectional side view of a portion of an illustrative electronic device having a window for a light-based component in accordance with an embodiment.

FIG. 5 is a cross-sectional side view of an illustrative active pixel in an active area of a display such as an organic light-emitting diode display in accordance with an embodiment.

FIGS. 6 and 7 are cross-sectional side view of illustrative dummy pixels in an inactive area of a display such as an organic light-emitting diode display in accordance with an embodiment.

FIG. 8 is a cross-sectional side view of an illustrative display region with an optical window formed by a polarizer with an unpolarized region such as a region of bleached polarizer material in accordance with an embodiment.

FIG. 9 is a cross-sectional side view of an illustrative display region with an optical window formed from a through-hole opening in a polarizer in accordance with an embodiment.

### DETAILED DESCRIPTION

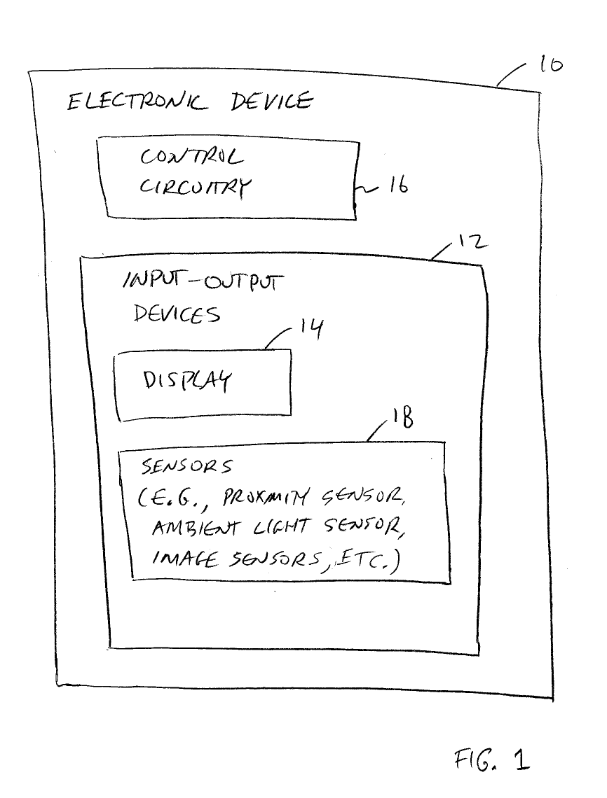

An illustrative electronic device of the type that may be provided with one or more light-based devices such as light sensors is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment.

As shown in FIG. 1, electronic device 10 may have control circuitry 16. Control circuitry 16 may include storage and processing circuitry for supporting the operation of device 10. The storage and processing circuitry may include storage such as nonvolatile memory (e.g., flash memory or other electrically-programmable-read-only memory configured to form a solid state drive) and volatile memory (e.g., static or dynamic random-access-memory). Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, light-emitting diodes for components such as status indicators, data ports, etc. A user can control the operation of device 10 by supplying commands through input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements.

Input-output devices 12 may also include sensors 18. Sensors 18 may include a capacitive proximity sensor, a light-based proximity sensor, an ambient light sensor, a light-based fingerprint sensor, a fingerprint sensor based on a capacitive touch sensor, a magnetic sensor, an accelerometer, a force sensor, a touch sensor for a button or track pad, a temperature sensor, a pressure sensor, a compass, a microphone, a visible digital image sensor (visible-light camera), an infrared digital image sensor (infrared-light camera), and other sensors.

Sensors 18 may be used to gather user commands (e.g., commands that direct control circuitry 16 to take action), may be used to gather information on the environment surrounding device 10 (e.g., information on ambient light levels, ambient temperature, ambient atmospheric pressure, etc.), and may be used in performing biometric authentication operations (e.g., using a fingerprint sensor, using visible and/or infrared cameras, using voice recognition, etc.). After a user has been authenticated using biometric authentication operations and/or after entering a password or supplying other information to device 10, control circuitry 16 may provide the user with access to the features of device 10 (e.g., circuitry 16 may allow the user to make telephone calls, access stored information in storage in device 10, send text messages or email messages, etc.).

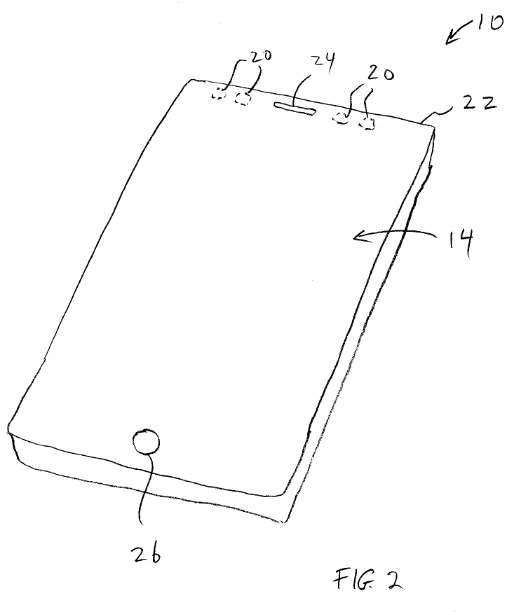

A perspective view of a portion of an illustrative electronic device is shown in FIG. 2. As shown in FIG. 2, electronic device 10 may be a portable electronic device such as a handheld device having opposing front and rear faces. In the example of FIG. 2, device 10 includes a display such as display 14 mounted in housing 22 on the front face of device 10. Configurations in which display 14 is mounted in other portions of an electronic device may be used, if desired (e.g., configurations in which display 14 is mounted to the upper housing in a laptop computer that has upper and lower housings coupled by a hinge, configurations in which display 14 is mounted to a housing in an all-in-one desktop computer, etc.). Housing 22, which may sometimes be referred to as an enclosure or case, may be formed of plastic, glass, ceramics, fiber composites, metal (e.g., stainless steel, aluminum, etc.), other suitable materials, or a combination of any two or more of these materials. Housing 22 may be formed using a unibody configuration in which some or all of housing 22 is machined or molded as a single structure or may be formed using multiple structures (e.g., an internal frame structure, one or more structures that form exterior housing surfaces, etc.).

Display 14 may be protected using a display cover layer such as a layer of transparent glass, clear plastic, sapphire, or other clear layer. Openings may be formed in the display cover layer. For example, an optional opening may be formed in the display cover layer to accommodate speaker port 24 or other components. An optional opening may be formed in the cover layer to accommodate button 26 or button 26 may be a virtual button formed by a sensor operating through pixels in display 14. Openings may be formed in housing 22 to form communications ports (e.g., an audio jack port, a digital data port, etc.), to form openings for buttons, etc.

Display 14 may be a liquid crystal display, may be an electrophoretic display, may be an organic light-emitting diode display or other display with an array of light-emitting diodes, may be a plasma display, may be an electrowetting display, may be a display based on microelectromechanical systems (MEMs) pixels, or may be any other suitable display. Illustrative configurations in which display 14 is an organic light-emitting diode display may sometimes be described herein as an example.

Openings or other transparent regions in one or more of the layers of display 14 may be used in forming optical windows 20. There may be any suitable number of windows 20 in display 14 (e.g., at least one, at least two, at least three, at least four, two, four, fewer than ten, 3-7, etc. In the example of FIG. 2, there are four windows 20, each of which overlaps an associated light sensor (e.g., a visible image sensor, an infrared image sensor with an optional infrared light-emitting diode for providing illumination, a color ambient light sensor, and an optical proximity sensor having an infrared light-emitting diode and a corresponding infrared light detector for detecting emitted infrared light that has reflected from an external object, and/or other light-based components in sensors 18). In general, there may be any suitable number of light-transmitting windows in display 14 and these windows may be used in transmitting emitted and/or received visible light, infrared light, and/or other light.

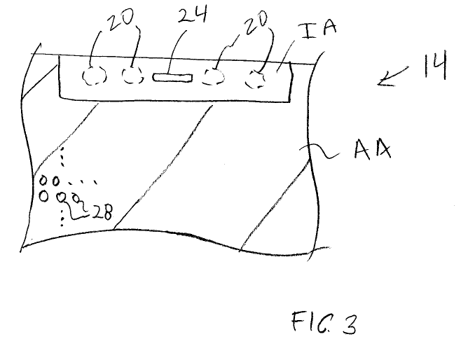

Display 14 may include an active area that contains an array of pixels for displaying images to a user. The overall footprint (shape when viewed from above) of display 14 may be rectangular or may have other suitable shapes. Display 14 may, for example, have a rectangular shape and the active area of display 14 may fill most of this rectangular shape. Inactive areas may be formed along one or more of the edges of the active area. As shown in FIG. 3, for example, inactive area IA may extend along part of the upper edge of display 14 and may overlap windows 20 and, if desired, may overlap speaker port 24. Active area AA may cover the remainder of the front face of device 10 and may include an array of pixels 28 for displaying images for a user. In some configurations, inactive areas may run along the left and right edges of display 14 and/or along the lower edge of display 14. In other configurations, display 14 is borderless along the right, left, and lower edges of display 14.

To provide display 14 with a uniform appearance, the display cover layer and polarizer for display 14 may extend over most or all of the front face of device 10. Openings for optional speaker port 24 and optional button 26 may, if desired, be formed through the display cover layer and polarizer. Optical windows 20 may be formed under the display cover layer in inactive area IA. To enhance light transmission and avoid other optical effects due to the presence of the polarizer, each optical window 20 may include a transparent region in the polarizer that is in alignment with that window 20. The transparent region may be formed by creating an opening in the polarizer or by rendering polarizer material transparent by bleaching or other processing techniques.

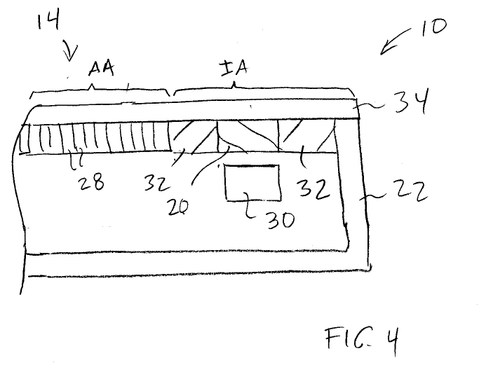

A cross-sectional side view of a portion of device 10 (e.g., an upper edge of device 10) is shown in FIG. 4. As shown in FIG. 4, display 14 may have active area AA for displaying images for a user. Active area AA contains pixels 28. Display cover layer 34 (e.g., a layer of glass, clear plastic, or other transparent material) may cover active area AA to protect pixels 28. Display cover layer 34 may extend across the front face of device 10 and may cover inactive areas such as inactive area IA. If, for example, device housing 22 has a rectangular shape with four straight sidewalls (left, right, lower, and upper), display cover layer 34 may have a rectangular shape and may extend from the left to right sidewall and from the lower to upper sidewall.

Optical window 20 may be formed in inactive area IA in alignment with optical component 30. Optical component 30 may be a light-based component such as an ambient light sensor, proximity sensor, visible light image sensor, infrared light image sensor, and/or other light sensor or light-based component (e.g., a light sensor in sensors 18 of FIG. 1). Optical window 20 may be transparent at visible and/or infrared wavelengths. For example, in scenarios in which component 30 operates at visible wavelengths, window 20 may be at least partly transparent at visible wavelengths. In scenarios in which component 30 operates at infrared wavelengths, window 20 may be at least partly transparent at infrared wavelengths. The transparency of window 20 allows light that is emitted by optical component 30 and/or light that is received by component 30 to pass through window 20 (including the transparent portions of layer 34 that are associated with window 20). The transparency of window 20 may be at least 70%, at least 80%, at least 90%, at least 95%, less than 99.999%, or other suitable value.

Inactive area IA is free of pixels, so there is a potential for visual differences to be present between active area AA and IA when a user of device 10 observes display 14 while display 14 is off. These visual differences can be minimized by forming dummy pixels 32 in inactive area IA. The dummy pixels may have appearances (e.g., light reflection characteristics as a function of viewing angle) that are similar or identical to pixels 28 of the active area (e.g., color coordinate values and/or light reflectivity values that differ by less than 25%, less than 10%, less than 5%, less than 2%, more than 0.1%, or other suitable value) and that therefore provide at least some of inactive area IA (e.g., portions of IA that do not overlap windows 22 and/or that do not lie within a narrow border region immediately adjacent to windows 22) with an appearance that matches that of active area AA.

Dummy pixels 32, which may sometimes be referred to as inactive pixels, may be formed using the structures of active pixels such as pixels 28 of active area AA that have been modified to prevent the dummy pixels from emitting light during operation of display 14.

FIG. 5 is a cross-sectional side view of an illustrative pixel configuration for active pixels 28 of active area AA. As shown in FIG. 5, pixel 28 may be formed on a substrate with one or more substrate layers 68 (e.g., one or more layers of polyimide, adhesive, buffer layers, etc.). Thin-film transistor circuitry may be formed on substrate 68. The thin-film transistor circuitry of display 14 may form pixel circuits for controlling the application of drive current in each pixel to an organic light-emitting diode in that pixel.

As shown in FIG. 5, the thin-film transistor circuitry of a pixel circuit may, for example, include transistors (e.g., switching transistors, drive transistors, emission enable transistors, and/or other transistors) such as a transistor formed from semiconductor layer 60 (e.g., a polysilicon layer or other semiconductor layer that forms an active region for the transistor), transistor source-drain terminals (e.g., source and drain terminals) formed from layers such as source-drain layer 56 and via 58), and a gate terminal formed from gate layer 62. The thin-film transistor circuitry may include insulating layers such as dielectric layers 66, 64, and 54. One or more dielectric planarization layers (e.g., organic planarization layers) such as layers 50 may be formed over the thin-film transistors.

Anode 48 may be formed from a layer of metal on layers 50. Via 52 may couple anode 48 to one of the source-drain terminals of a drive transistor formed in the thin-film transistor circuitry of the pixel circuit associated with pixel 28. Organic emissive material 46 may be formed in an opening in pixel definition layer 44 (e.g., an organic layer). Cathode 42 (e.g., a layer of metal that is sufficiently thin to be transparent) may overlap layer 44 and material 46 in the opening in layer 44. A transparent encapsulation layer such as thin-film encapsulation layer 40 may cover pixel 28. Anode 48, emissive material 46, and cathode 42 form an organic light-emitting diode for pixel 28. When current passes through this diode, light is emitted upwards through cathode 42 and encapsulation layer 40. The thin-film transistor circuitry of pixel 28 forms a pixel circuit that is coupled to the light-emitting diode. During operation of display 14, the pixel circuit controls the amount of drive current supplied to the light-emitting diode based on a loaded data value.

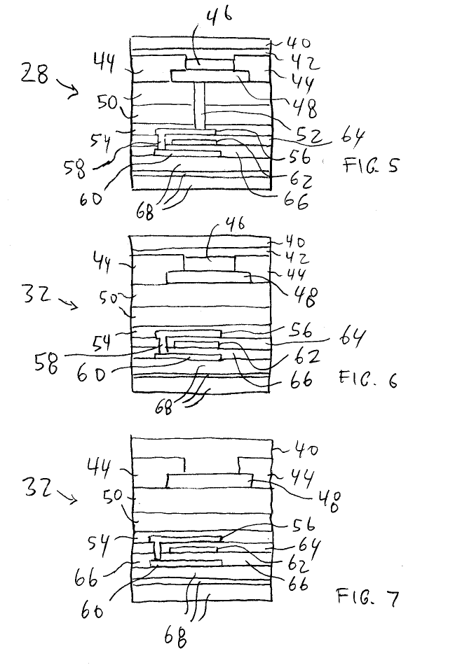

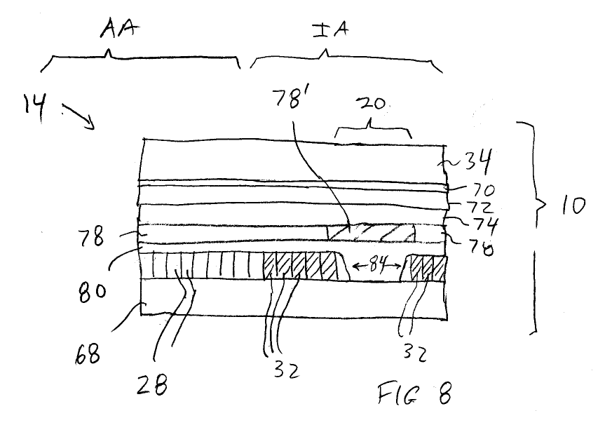

Dummy pixel structures such as illustrative dummy pixels 32 of FIGS. 6 and 7 may be structurally similar to the structures of pixel 28, but have missing metal structures or other differences from pixel 28 so that dummy pixels 32 are incapable of emitting light. Sufficient structures are present in dummy pixels 32 to closely match the external appearance of dummy pixels 32 to pixels 28 (e.g., to match the light reflection characteristics of pixels 28 as a function of viewing angle including reflection intensity, reflection color, etc.). As a result, incorporation of dummy pixels 32 into inactive area IA of display 14 may help match the visual appearance of inactive area IA to that of active area AA when display 14 is off, thereby enhancing the attractiveness of device 10.

In the example of FIG. 6, dummy pixel 32 has no via 52 (FIG. 5), so anode 48 is floating and is not coupled to the underlying drive transistor (e.g., source-drain terminal 56). As a result of disconnecting anode 48 from the thin-film transistor circuitry of display 14, the diode of dummy pixel 32 is not supplied with drive current and does not emit light.

In the example of FIG. 7, cathode 42 (FIG. 5) and organic emissive material 46 (FIG. 5) have been omitted, so that there is no diode in dummy pixel 32. As a result, the dummy pixel of FIG. 7 does not emit light.

If desired, other dummy pixel structures may be formed that help match the visual appearance of inactive area IA to that of active area AA. For example, other structures in pixels 28 can be omitted, disconnected, or otherwise modified to ensure that the remaining structures (metal routing, polysilicon structures, organic emissive layers, anode, cathode, dielectric layers, etc.) do not form an active pixel.

The structures of dummy pixels 32 of FIGS. 6 and 7 can be formed in inactive area IA at the same time that pixels 28 are being formed in active area AA. It is not necessary to use significant additional fabrication steps or additional photolithographic masks to form dummy pixels 32, because the structures of dummy pixels 32 can be formed while pixels 28 are being fabricated with minimal process modifications.

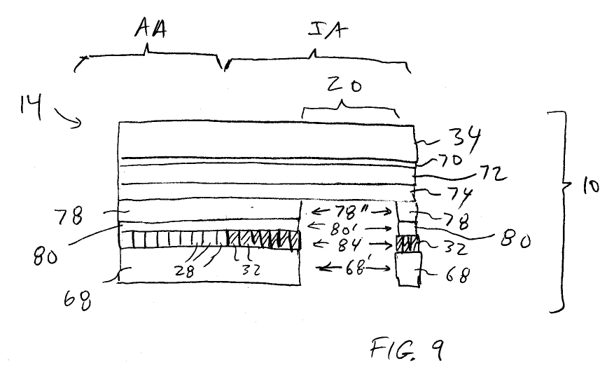

FIG. 8 is a cross-sectional side view of a portion of device 10 showing how optical window 22 may be formed from an unpolarized region in a polarizer. In the illustrative configuration for display 14 of FIG. 8, active area AA includes pixels 28 and inactive area IA includes dummy pixels 32 surrounding optical window 20. Touch sensor layer 72 (e.g., a two-dimensional capacitive touch sensor formed from transparent electrodes such as indium tin oxide electrodes on a clear substrate) may be interposed between the pixel array formed by pixels 28 (and dummy pixels 32) and display cover layer 34. Adhesive layer 70 may be used to attach touch sensor layer 72 to the underside of display cover layer 34. Adhesive layer 74 may be used to attach polarizer 78 to the underside of touch sensor layer 72. Polarizer 78 may have an unpolarized portion such as unpolarized portion 78′ that is aligned with optical window 20. Polarizer 78 may, as an example, be formed from polymer films such as an iodine-doped polyvinyl alcohol polarizing layer sandwiched between a pair of tri-acetyl cellulose layers and unpolarized portion 78′ may be a region of polarizer 78 from which the iodine-doped polyvinyl alcohol layer has been omitted, has been removed (e.g., by laser ablation, cutting, etc.), or has been rendered inactive at polarizing light by chemical bleaching, light bleaching, or other selective treatment.

Pixels 28 and dummy pixels 32 may be formed on transparent substrate 68. Encapsulation layer 80 (e.g., an encapsulation layer such as layer 40 of FIGS. 6, 7, and 8 and/or an additional transparent encapsulation layer) may cover an array of pixels 28 in active area AA and an array of dummy pixels 32 in inactive area IA. Opening 84 in dummy pixels 32 is aligned with window 20. Opening 84 may be circular and surrounded by dummy pixels 32 on all sides or may have a U-shape that terminates along the adjacent edge of housing 22 (e.g., so that dummy pixels 32 are adjacent to opening 84 on at least one, at least two, or at least three sides of opening 84).

Due to the presence of opening 84, pixel structures such as pixel definition layer 44, organic emissive layer 46, and associated thin-film transistor circuit layers are not present in in window 20. Unpolarized region 78′ does not polarize light and therefore may have a relatively high transmission (e.g., greater than 50%, at least 60%, at least 70%, at least 80%, at least 90%, at least 95%, less than 99.999%, 80-99%, more than 65%, more than 75%, or other suitable amount). Display cover layer 34, adhesive layers 70 and 74, touch sensor layer 72, encapsulation layer 80, and substrate 68 may also exhibit high transmission values. As a result, optical window 20 is transparent and may exhibit high light transmission (e.g., greater than 50%, at least 60%, at least 70%, at least 80%, at least 90%, at least 95%, less than 99.999%, 80-99%, more than 65%, more than 75%, or other suitable amount).

FIG. 9 is a cross-sectional side view of a portion of device 10 showing how optical window 22 may be formed from a physical opening in polarizer 78 such as a through-hole opening. As with the illustrative configuration of FIG. 8, the illustrative configuration for display 14 of FIG. 9 has an active area AA including pixels 28 and an inactive area IA with dummy pixels 32. Touch sensor layer 72 (e.g., a two-dimensional capacitive touch sensor formed from transparent electrodes such as indium tin oxide electrodes on a clear substrate) may be interposed between the pixel array formed by pixels 28 (and dummy pixels 32) and display cover layer 34. Adhesive layer 70 may be used to attach touch sensor layer 72 to the underside of display cover layer 34 and adhesive layer 74 may be used to attach polarizer 78 to the underside of touch sensor layer 72.

Polarizer 78 of FIG. 9 may have an opening such as opening 78″ that is aligned with optical window 20. Opening 78″ and other openings in window 20 may be filled with clear polymer or may be filled with air. Pixels 28 and dummy pixels 32 may be formed on transparent substrate 68. Encapsulation layer 80 (e.g., an encapsulation layer such as encapsulation layer 40 of FIGS. 6, 7, and 8, and/or other clear encapsulation material) may cover an array of pixels 28 in active area AA and an array of dummy pixels 32 in inactive area IA. Encapsulant 80 may have an opening such as opening 80′ that is aligned with window 20. Opening 84 in dummy pixels 32 and opening 68′ in substrate 68 may also be aligned with window 20. Opening 84 may be circular and surrounded by dummy pixels 32 on all sides or may have a U-shape that terminates along the adjacent edge of housing 22 so that dummy pixels 32 are adjacent to one, two, or three sides of opening 84 (as examples). Due to the presence of opening 78″ and the other openings aligned with window 20, opaque structures are not present in window 20 so that window 20 will be transparent. Optical window 20 can therefore exhibit high light transmission (e.g., greater than 50%, at least 60%, at least 70%, at least 80%, at least 90%, at least 95%, less than 99.999%, 80-99%, more than 65%, more than 75%, or other suitable amount).

Any suitable fabrication techniques may be used in forming openings for window 20 of FIG. 9. For example, these openings may be formed by laser ablation (e.g., using ultraviolet light with a wavelength of 355 nm or other suitable wavelength in 12 ps pulses or pulses of other duration such as femtosecond pulses). Laser processing techniques may be used to form openings from the top or bottom of the display layers. Openings may, if desired, be formed before stacking the layers of display 14 together. With this type of arrangement, the pixel structures and other layers of the display may be laminated to other layers in device 10 such as touch sensor layer 72, cover layer 34, etc. following hole formation.

Physical opening arrangements of the type shown in FIG. 9 exhibit good off-axis optical performance (e.g., no color shifts for light passing through window 20 at different angles). Bleached polarizer arrangements of the type shown in FIG. 8 may help minimize panel cuts and process complexity.

The foregoing is merely illustrative and various modifications can be made to the described embodiments. The foregoing embodiments may be implemented individually or in any combination.

What is claimed is:

1. An electronic device having opposing front and rear faces, comprising:
a housing with edges;
a polarizer layer covering the front face and extending between the edges;
an organic light-emitting diode display that is covered by the polarizer layer and that has an active area with pixels that display images and an inactive area with dummy pixels in which no images are displayed; and
a light-based component in the housing, wherein the polarizer layer and the organic light-emitting diode display are configured to form an optical window in the inactive area that is in alignment with the light-based component.

2. The electronic device defined in claim 1 wherein the inactive area is formed along one of the edges and wherein the polarizer layer has an opening in alignment with the optical window.

3. The electronic device defined in claim 2 wherein the dummy pixels have an opening in alignment with the optical window and are overlapped by the polarizer layer.

4. The electronic device defined in claim 2 wherein the light-based component comprises an ambient light sensor.

5. The electronic device defined in claim 2 wherein the light-based component comprises a proximity sensor.

6. The electronic device defined in claim 2 wherein the light-based component comprises an image sensor.

7. The electronic device defined in claim 2 wherein each of the dummy pixels includes thin-film transistor circuitry and an anode that is disconnected from the thin-film transistor circuitry.

8. The electronic device defined in claim 2 wherein each of the dummy pixels includes an organic light-emitting diode anode and does not include an organic light-emitting diode cathode.

9. The electronic device defined in claim 8 wherein each of the dummy pixels includes thin-film transistor circuitry and does not include organic emissive material adjacent to the organic light-emitting diode anode.

10. An electronic device having opposing front and rear faces, comprising:
a housing with edges;
a polarizer layer covering the front face and extending between the edges;
an organic light-emitting diode display that is covered by the polarizer layer and that has an active area with pixels that display images and an inactive area with dummy pixels in which no images are displayed; and
a light-based component in the housing, wherein the polarizer layer and the organic light-emitting diode display are configured to form an optical window in the inactive area in alignment with the light-based component and wherein the polarizer layer has an unpolarized portion in alignment with the optical window.

11. The electronic device defined in claim 10 wherein the inactive area is formed along one of the edges and wherein the dummy pixels have an opening in alignment with the optical window and are overlapped by the polarizer layer.

12. The electronic device defined in claim 11 wherein the unpolarized portion comprises a bleached portion of the polarizer that is configured to pass light without polarizing the light.

13. The electronic device defined in claim 10 wherein the light-based component comprises a light sensor.

14. The electronic device defined in claim 13 wherein the light sensor comprises a sensor selected from the group consisting of: an ambient light sensor, an optical proximity sensor, and an image sensor.

15. The electronic device defined in claim 14 wherein each of the dummy pixels includes thin-film transistor circuitry and an anode that is disconnected from the thin-film transistor circuitry.

16. The electronic device defined in claim 14 wherein each of the dummy pixels includes an organic light-emitting diode anode and does not include an organic light-emitting diode cathode.

17. The electronic device defined in claim 14 wherein each of the dummy pixels includes an anode and does not include organic emissive material adjacent to the anode.

18. Apparatus, comprising:
an array of pixels configured to display images;
dummy pixels that do not display images;
an optical window adjacent to the dummy pixels;
a light-based component in alignment with the optical window; and
a polarizer having a transparent portion aligned with the optical window.

19. The apparatus defined in claim 18 wherein the transparent portion is formed from an opening in the polarizer.

20. The apparatus defined in claim 19 wherein the transparent portion is formed from an unpolarized portion of the polarizer.
